(19) United States
(12) Patent Application Publication
(10) Pub. No.: US 2007/0108638 A1
(43) Pub. Date: May 17, 2007

(54) ALIGNMENT MARK WITH IMPROVED RESISTANCE TO DICING INDUCED CRACKING AND DELAMINATION IN THE SCRIBE REGION

(75) Inventors: Michael W. Lane, Cortlandt Manor, NY (US); Christopher D. Muzzy, Burlington, VT (US); Roger J. Yerdon, Pleasant Valley, NY (US)

Correspondence Address: LAW OFFICE OF DELIO & PETERSON, LLC., 121 WHITNEY AVENUE, NEW HAVEN, CT, 06510, US

(73) Assignee: INTERNATIONAL BUSINESS MACHINES CORPORATION, ARMONK, NY (US)

(21) Appl. No.: 11/164,266

(22) Filed: Nov. 16, 2005

(51) Int. Cl. H01L 23/544; H01L 21/78

(52) U.S. Cl. 257/797; 438/462

(57) ABSTRACT

A robust alignment mark used in semiconductor processing to help deter the expansion of cracks and delamination caused by the cutting of a dicing blade. A cross-shaped structure is used as a line site for alignment of the dicing blade. A plurality of rectangular elements is situated about the periphery of the alignment mark and populated with via bar structures that are interconnected at each level of the wafer, and laid in a serpentine fashion throughout each element to expose more of the via bar structure surface area to propagating cracks. The rectangular elements are formed of different sizes to expose more surface area to propagating cracks. A plurality of square, metal-level structures is formed in the area between the cross-shaped structure and the peripherally placed, rectangular elements.

### BACKGROUND OF THE INVENTION

1. Field of the Invention

This invention relates to structures for preventing cracks from propagating during dicing. More particularly, it relates to resisting dicing induced cracking and delamination on semiconductor wafers. Even more particularly, it relates to patterned structures embedded within the alignment features on a semiconductor wafer that reduce or prevent damage to the integrated circuit by the dicing blade during cutting.

2. Description of Related Art

Delamination cracks caused by dicing can propagate across an integrated circuit chip inwards from the edge to active regions. These cracks can cause electrical openings or shorts, and ultimately cause failure of the semiconductor chip. The delamination typically allows moisture and other impurities to penetrate in the semiconductor wafer. Typically, the delamination induced by dicing is due, in part, to reduced adhesion or reduced mechanical strength materials that are subject to the external forces of the dicing blade.

Delamination or cracking generally starts at the edge of the die during a dicing operation and propagates towards the center of the die. If the delamination or crack reaches an electrical interconnect, the forces within the die that caused the delamination or crack propagation act upon the electrical interconnect causing the electrical interconnect to rip apart at its weak points.

Various techniques have been used in industry to prevent or control delamination or cracking. Traditionally, crack stops have been placed in the die or at the edges of the die to prevent both delamination and cracks from propagating within the active die area. However, there has been little effort to control crack propagation or delamination at the alignment structures that receive the dicing blade. The alignment structures are normally situated in the scribe region of the wafer, which is generally defined as the area between the active die. By implementing a more robust alignment structure design, defects due to dicing are significantly reduced in the scribe region, thus minimizing crack and delamination propagation into the active die area.

There are a number of prior art techniques that have been implemented to solve the problem of crack propagation and delamination during dicing; however, these techniques do not apply to the alignment structures themselves, as discussed below.

In U.S. Pat. No. 6,399,897 issued to Umematsu, et al., on Jun. 4, 2002, entitled “MULTI-LAYER WIRING SUBSTRATE,” a plurality of insulating films is stacked on a main substrate. The insulating films have wiring patterns formed on wiring regions, and dummy-wiring patterns formed on peripheral regions. The structure is designed for multi-chip module (MCM) packaging. The stacked films are at the metal levels, and the dummy fills are associated with a large film stack. Importantly, the wiring patterns are arranged around the entire substrate, and are not part of the alignment structure. In contrast, the present invention utilizes stacked vias inside alignment structures that direct the dicing blade. The stacked vias are associated with small metal pads at the metal levels, situated about and within the alignment structure.

In U.S. Pat. No. 6,163,065 issued to Seshan, et al., on Dec. 19, 2000, entitled “ENERGY-ABSORBING STABLE GUARD,” a guard ring is designed within the active die area. The guard ring has zigzag shaped portions at the corners of the integrated circuit chip to absorb energy caused by delamination, thin-film cracking, and other types of mechanical and chemical damage. Unlike the Seshan design, the present invention reinforces the alignment structures in the scribe region to suppress directly the dicing blade forces. Furthermore, the stacked via fills of the present invention are used with a plurality of individual via-filled elements populating the center region of the alignment structure.

In U.S. Pat. No. 6,521,975 issued to West, et al., on Feb. 18, 2003, entitled “SCRIBE STREET SEALS IN SEMICONDUCTOR DEVICES AND METHOD OF FABRICATION,” two sets of substantially parallel structures within seal regions extend along the edge of a chip on opposite sides of each dicing line. Importantly, the parallel structures of West are outside the dicing lane, and are not used as alignment features for the dicing blade. Furthermore, the present invention includes numerous layers of structures, close to one another, to provide redundant protection against the propagation of cracks or delamination in the alignment structure.

### SUMMARY OF THE INVENTION

Bearing in mind the problems and deficiencies of the prior art, it is therefore an object of the present invention to provide an apparatus for preventing dicing damage to semiconductor wafers.

It is another object of the present invention to provide an apparatus for a robust alignment structure in a semiconductor wafer that suppresses delamination and crack propagation.

A further object of the invention is to provide an apparatus to prevent dicing damage within the scribe region of a semiconductor wafer and simultaneously enhance chip space.

It is yet another object of the present invention to provide an apparatus for providing a redundant alignment structure protection scheme on an alignment feature to prohibit or deter delamination and crack propagation during dicing.

Still other objects and advantages of the invention will in part be obvious and will in part be apparent from the specification.

The above and other objects, which will be apparent to those skilled in art, are achieved in the present invention, which is directed to an alignment mark for resisting dicing induced cracks and delamination on a semiconductor wafer during wafer processing, comprising: a cross-shaped structure centered about the alignment mark for guiding a dicing blade; and a plurality of shaped connecting elements having at least two different sizes, the connecting elements arranged about the alignment mark periphery in an alternating pattern to maximize surface area exposure, the connecting elements fabricated and interconnected through each layer of the wafer. The alignment mark further comprises a plurality of via bar structures fabricated within the connecting elements, the via bar structures interconnected through each layer of the wafer. The alignment mark may also comprise a plurality of via bar structures fabricated within the cross-shaped structure, the via bar structures interconnected through each layer of the wafer. The via bar structures may form a serpentine pattern parallel to the alignment mark edges, the serpentine pattern having adjacent via bar structural elements approximately perpendicular to one another. The via bar structures may be spaced approximately 2.5 times the minimum the design rule spacing dimension. The alignment mark may also include a plurality of vertical structures formed within an area between the connecting elements and the cross-shaped structure, the vertical structures interconnected through each layer of the wafer.

In a second aspect, the present invention is directed to an alignment mark for resisting dicing induced cracks and delamination on a semiconductor wafer during wafer processing, comprising: a cross-shaped structure centered about the alignment mark for guiding a dicing blade; a plurality of shaped connecting elements having at least two different sizes, the connecting elements arranged about the alignment mark periphery in an alternating pattern to maximize surface area exposure, the connecting elements fabricated and interconnected through each layer of the wafer; corner elements fabricated and interconnected through each layer of the wafer, the corner elements arranged on each corner of the alignment mark; and a plurality of vertical structures formed within an area between the connecting elements and the cross-shaped structure, the vertical structures interconnected through each layer of the wafer.

### BRIEF DESCRIPTION OF THE DRAWINGS

The features of the invention believed to be novel and the elements characteristic of the invention are set forth with particularity in the appended claims. The figures are for illustration purposes only and are not drawn to scale. The invention itself, however, both as to organization and method of operation, may best be understood by reference to the detailed description which follows taken in conjunction with the accompanying drawings in which:

FIG. 1 depicts a schematic of an alignment mark of the prior art having a cross-shaped structure for the dicing blade, and individual surface structures about the periphery.

FIG. 2 depicts dicing blade cuts through the alignment mark of FIG. 1.

FIG. 3 depicts a schematic of an alignment mark feature of the present invention.

FIG. 4 depicts a via bar structure associated with rectangular elements for the corner sections and the straight sections.

FIG. 5 depicts the third level of protection, including a number of elements aligned in an array fashion between the cross-shaped structure and the rectangular elements, with via structures therein.

### DESCRIPTION OF THE PREFERRED EMBODIMENT(S)

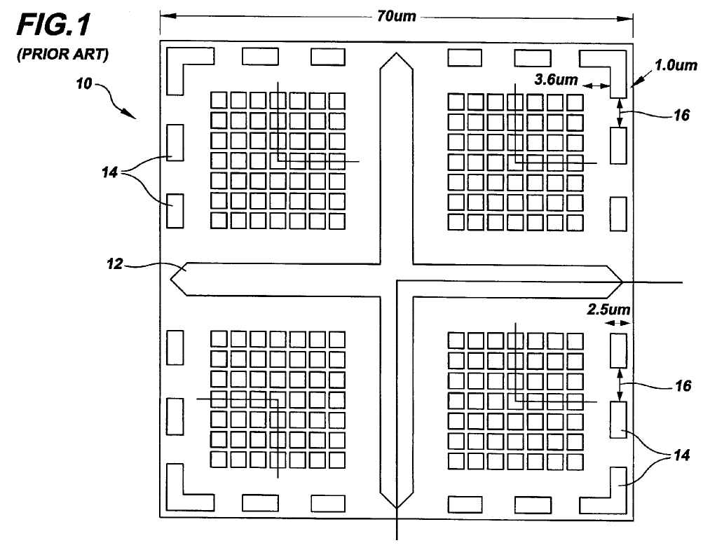

In describing the preferred embodiment of the present invention, reference will be made herein to FIGS. 1-5 of the drawings in which like numerals refer to like features of the invention.

Stacked via fills of a finite width along a chip edge can prevent the chip from the cracking and delaminating that will ultimately occur during dicing. Preferably, the stacked via fills connect from the bottom of the wafer to the topmost oxide layer, and are either electrically active or dummy vias, but nonetheless, yield a strong structure to protect the weak dielectrics around them.

FIG. 1 depicts a schematic of an alignment mark 10 of the prior art having a cross-shaped structure 12 for dicing blade alignment, and individual surface structures 14 about the periphery. The alignment mark 10 is typically about 70 microns in width, with individual surface structures 14 about the periphery measuring approximately 2.5 microns in width. Surface structures 14 are spaced apart with gaps 16 therebetween. They are not connected to underlying levels. Nor do they comprise multiple layered via bar structures. They are all of the same size and shape, and are not designed to expose additional surface area to propagating cracks.

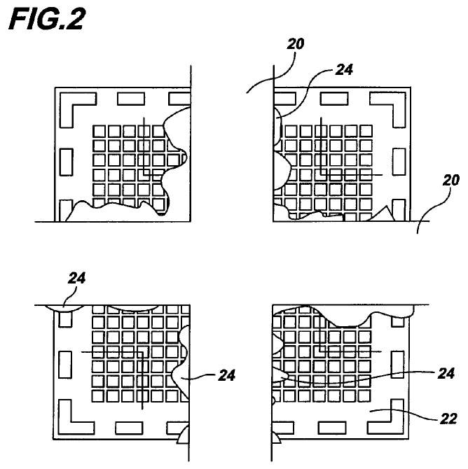

FIG. 2 depicts dicing blade cuts 20 through an alignment mark 22 of the prior art. Dicing blade cuts 20 are shown to produce lamination points 24 at alignment mark 22. The lamination 24 is shown extending outwards from cuts 20.

Generally, the cross-shaped alignment marks are present at each corner of the die field. The alignment mark is located in the scribe region and is used to verify the dicing alignment. Importantly, the alignment mark increases the resistance to delamination and cracking during the dicing operation at the location where the dicing blade crosses the alignment feature. The size of the alignment marks normally is scaled in proportion to the size of the scribe region width.

In the present invention, an interconnection structure is added to the semiconductor wafer at the closest possible point to the dicing saw blade path. The interconnection structure is formed at the alignment marks used for guiding the dicing blade. Preferably, the interconnection structure is made of stacked via fills. These stacked via fills, when closely spaced to fill the chip edges, provide mechanical strength to prevent chip-cracking propagation, enhance the scribe region, and increase resistance to delamination.

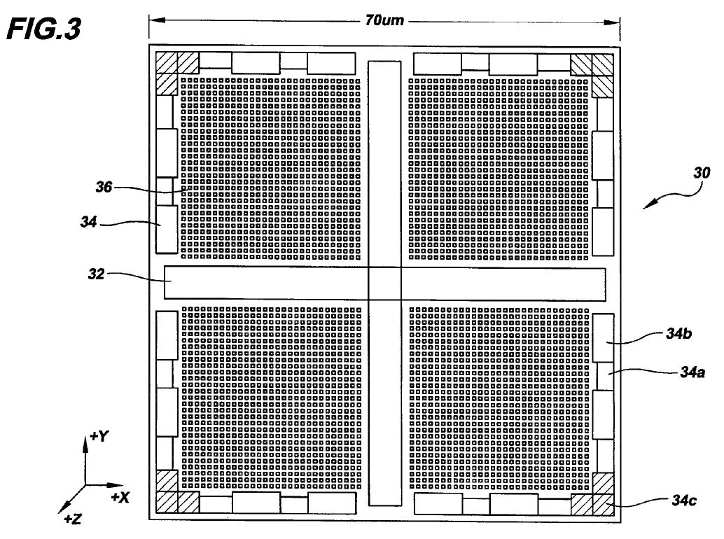

Three basic elements are introduced to make an alignment mark feature more robust to dicing induced failures. FIG. 3 depicts a schematic of an alignment mark feature 30 of the present invention. Like the prior art, the alignment mark 30 includes a cross-shaped structure 32. However, in the present invention, the cross-shaped structure is reinforced with a plurality of via bar structures. The via bar structures are preferably shaped in a serpentine pattern, and redundantly employed throughout cross-shaped structure 32. This first element remains important for the alignment and alignment verification process, but does not remain after dicing, as its width is generally smaller than the dicing blade. The via bars within cross-shaped structure 32 contribute to reducing crack propagation and delamination. The cross-shaped structure 32 and accompanying via bars are repeated at each mask level, and is generally made of the particular metal used for the chip.

The second element in alignment mark 30 that contributes to making the mark more robust to cracking and delamination is a plurality of metal structures 34, preferably rectangular in shape, aligned about the periphery of the alignment mark. The metal structures 34 encircle the alignment mark. Some metal structures 34 are cut by the dicing blade as the blade traverses its path through cross-shaped structure 32 in the alignment mark. In the preferred embodiment, element metal structures 34 include at least two alternating rectangular sizes, 34a and 34b, although other shapes may be successfully employed in the same manner as the rectangular shapes depicted in FIG. 3. Corner sections 34c are also depicted. The corner section may be a separate and distinct element or a combination of other rectangular structures. By employing alternating shapes of smaller and larger rectangles more surface area is exposed to a propagating crack in the x- and y-directions induced by the dicing process. Although rectangular shapes are preferred, any set of shaped elements that increases the vertical surface area exposed to a propagating crack from a dicing blade cut would contribute to a more robust protective structure.

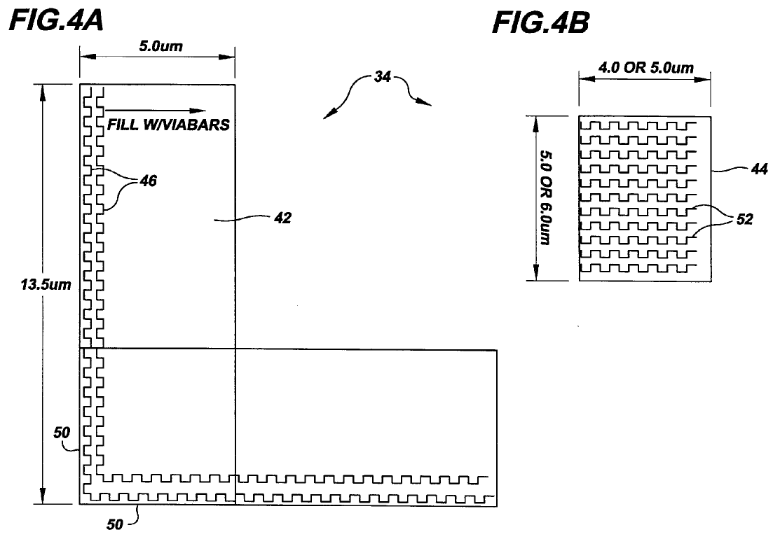

Each metal level of rectangular elements 34 throughout the wafer are vertically connected in the z-axis direction from the water bottom to the wafer top by specifically aligned via bar structures. FIGS. 4A and 4B depict a corner piece 42 and connecting piece 44, associated with rectangular elements 34 that constitute the corner sections and the straight sections. Inside each element is a plurality of via bar structures, preferably shaped in a serpentine pattern, and redundantly employed throughout the rectangular elements 34. In the corner section 42, the serpentine via bar structures 46 follows the outside edges 50 of the element. Preferably, adjacent via bar structures are placed apart on the order of 2.5 times the minimum design rule spacing dimension. For example, if the ground rule is 0.1 micron, the via bar structures are placed approximately 0.25 microns apart. In the example shown in FIG. 4A, the corner section 42 is approximately 5 microns wide and 13.5 microns in length. Consequently, as many as 20 serpentine, parallel via bar structures may be aligned 0.25 microns apart across the 5 micron width. Each via bar structure provides a line of defense against propagating cracks and delamination. The redundancy helps reduce the propagation. If a via bar structure breaks under the propagating crack forces, the next adjacent via bar structure is directly behind to mitigate the destructive propagating forces.

FIG. 4B depicts the via bar structure 52 of connecting piece element 44. Preferably, parallel, serpentine via bars 52 populate connecting piece element 44 in a similar fashion to those that populate the corner via bar structure 42. Connecting piece element 44 may be employed in different rectangular sizes, such as, 4.0×5.0 microns, 4.0×6.0 microns, 5.0×5.0 microns, or 5.0×6.0 microns, and the like. The present invention is not restricted to certain rectangular sizes, nor is the design limited to only two different types of rectangular elements. A number of different rectangular sized elements may be utilized, provided that they are situated about the periphery with a plurality of surfaces showing in the z-direction in order to maximize the surface area exposed to a propagating crack.

By filling the available area underneath the alignment marks with robust interconnection structures that are fabricated at each level from the bottom of the wafer to the top, the dicing blade path is confronted at the closest possible point of contact with mechanical structures that deter crack propagation and delamination.

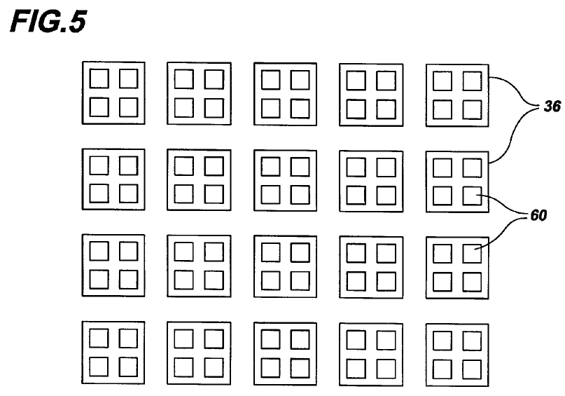

A third level of protection is depicted by element 36 shown in FIG. 3. Element 36 represents a plurality of square metal-level shaped structures connected above and below in the z-direction by via structures. Elements 36 fill the area between cross-shaped structure 32 and metal structures 34. They may be increased in size as the level design rules allow. These elements represent further mechanical protection against propagating cracks and delamination. They may be arrayed in a row and column manner across each quadrant of the alignment mark, separated by cross-shaped structure 32. Elements 36 may also be staggered in placement throughout the fill pattern, arranged in columns with offsetting rows to form a more diagonal arrangement. Other patterns are not precluded, provided elements 36 populate the fill between cross-shaped structure 32 and metal structures 34. FIG. 5 depicts a number of elements 36 aligned in an array fashion, having via structures 60 therein.

The present invention teaches a robust alignment mark used in semiconductor processing to help deter the expansion of cracks and delamination caused by the cutting of a dicing blade. Three levels of protection are employed. First, a cross-shaped structure is employed, which is typically used as a line site for alignment of the dicing blade. Second, a plurality of rectangular elements is situated about the periphery of the alignment mark. These rectangular elements are populated with via bar structures that are interconnected at each level of the wafer, and laid in a serpentine fashion throughout each element to expose more of the via bar structure surface area to propagating cracks. The via bar structures are laid in a number of adjacent rows parallel to the alignment mark edges to add redundant levels of mechanical strength to prohibit crack propagation. The rectangular elements are also preferably of different sizes to expose more surface area in the z-direction to propagating cracks. Third, a plurality of square, metal-level structures populates the area between the cross-shaped structure and the peripherally placed, rectangular elements. The square, metal-level structures are aligned in an array, and have via connections to each underlying level in the wafer, such that they form another barrier for crack propagation.

While the present invention has been particularly described, in conjunction with a specific preferred embodiment, it is evident that many alternatives, modifications and variations will be apparent to those skilled in the art in light of the foregoing description. It is therefore contemplated that the appended claims will embrace any such alternatives, modifications and variations as falling within the true scope and spirit of the present invention.

Thus, having described the invention, what is claimed is:

1. An alignment mark for resisting dicing induced cracks and delamination on a semiconductor wafer during wafer processing, comprising:
a cross-shaped structure centered about said alignment mark for guiding a dicing blade; and
a plurality of shaped connecting elements having at least two different sizes, said connecting elements arranged about said alignment mark periphery in an alternating pattern to maximize surface area exposure, said connecting elements fabricated and interconnected through each layer of said wafer.

2. The alignment mark of claim 1 further comprising a plurality of via bar structures fabricated within said connecting elements, said via bar structures interconnected through each layer of said wafer.

3. The alignment mark of claim 1 further comprising a plurality of via bar structures fabricated within said cross-shaped structure, said via bar structures interconnected through each layer of said wafer.

4. The alignment mark of claim 2 wherein said via bar structures form a serpentine pattern parallel to said alignment mark edges, said serpentine pattern having adjacent via bar structural elements approximately perpendicular to one another.

5. The alignment mark of claim 3 wherein said via bar structures form a serpentine pattern parallel to said alignment mark edges, said serpentine pattern having adjacent via bar structural elements approximately perpendicular to one another.

6. The alignment mark of claim 2 wherein said via bar structures are spaced by a factor of approximately 2.5 times the minimum design rule spacing dimension.

7. The alignment mark of claim 3 wherein said via bar structures are spaced by a factor of approximately 2.5 times the minimum design rule spacing dimension.

8. The alignment mark of claim 1 wherein said connecting elements comprise different rectangular sizes.

9. The alignment mark of claim 1 further including corner elements fabricated and interconnected through each layer of said wafer, said corner elements arranged on each corner of said alignment mark.

10. The alignment mark of claim 9 wherein said corner elements further comprise a plurality of via bar structures fabricated within said corner elements, said via bar structures interconnected through each layer of said wafer.

11. The alignment mark of claim 1 including a plurality of vertical structures formed within an area between said connecting elements and said cross-shaped structure, said vertical structures interconnected through each layer of said wafer.

12. The alignment mark of claim 11 wherein said vertical structures are aligned in an array having a row and column pattern.

13. The alignment mark of claim 11 wherein said vertical structures are aligned in a staggered array having offset columns or offset rows.

14. The alignment mark of claim 11 wherein said vertical structures include square shaped metal-level structures.

15. An alignment mark for resisting dicing induced cracks and delamination on a semiconductor wafer during wafer processing, comprising:
a cross-shaped structure centered about said alignment mark for guiding a dicing blade;
a plurality of shaped connecting elements having at least two different sizes, said connecting elements arranged about said alignment mark periphery in an alternating pattern to maximize surface area exposure, said connecting elements fabricated and interconnected through each layer of said wafer;
corner elements fabricated and interconnected through each layer of said wafer, said corner elements arranged on each corner of said alignment mark; and
a plurality of vertical structures formed within an area between said connecting elements and said cross-shaped structure, said vertical structures interconnected through each layer of said wafer.

16. The alignment mark of claim 15 further comprising a plurality of via bar structures fabricated within said connecting elements and said corner elements, said via bar structures interconnected through each layer of said wafer.

17. The alignment mark of claim 15 further comprising a plurality of via bar structures fabricated within said cross-shaped structure and said corner elements, said via bar structures interconnected through each layer of said wafer.

18. The alignment mark of claim 16 wherein said via bar structures form a serpentine pattern parallel to said alignment mark edges, said serpentine pattern having adjacent via bar structural elements approximately perpendicular to one another.

19. The alignment mark of claim 15 wherein said vertical structures are aligned in an array having a row and column pattern or a staggered array having an offset row or an offset column.

20. The alignment mark of claim 15 wherein said vertical structures include square shaped metal-level structures.
